(19) United States
(12) Patent Application Publication
(10) Pub. No.: US 2022/0336577 A1
(43) Pub. Date: Oct. 20, 2022

(54) METAL-INSULATOR-METAL (MIM) CAPACITOR AND METHOD OF FORMING AN MIM CAPACITOR

(71) Applicant: Microchip Technology Incorporated, Chandler, AZ (US)

(72) Inventor: Yaojian Leng, Portland, OR (US)

(73) Assignee: Microchip Technology Incorporated, Chandler, AZ (US)

(21) Appl. No.: 17/379,376

(22) Filed: Jul. 19, 2021

Related U.S. Application Data
(60) Provisional application No. 63/175,138, filed on Apr. 15, 2021.

(51) Int. Cl. H01L 49/02; H01L 21/768

(52) U.S. Cl. CPC H01L 28/91; H01L 21/76877

(57) ABSTRACT

A metal-insulator-metal (MIM) capacitor includes (a) a bottom electrode including (i) a bottom electrode plate and (ii) a bottom electrode cup formed from a conformal fill metal, (b) an insulator cup formed on the bottom electrode cup, (c) a top electrode formed in an opening defined by the insulator cup, and (d) a top electrode connection pad connected to the top electrode. The MIM capacitor may be formed concurrently with an interconnect structure including a lower interconnect element, an upper interconnect element, and interconnect via connected between the lower and upper interconnect elements. The bottom electrode plate and lower interconnect element may be formed in a lower metal layer, the top electrode connection pad and upper interconnect element may be formed in an upper metal layer, and the bottom electrode cup, insulator cup, top electrode, and interconnect vias may be formed between the lower and upper metal layers.

### RELATED APPLICATION

This application claims priority to commonly owned U.S. Provisional Patent Application No. 63/175,138 filed Apr. 15, 2021, the entire contents of which are hereby incorporated by reference for all purposes.

### TECHNICAL FIELD

The present disclosure relates to metal-insulator-metal (MIM) capacitors formed in integrated circuit structures.

### BACKGROUND

A metal-insulator-metal (MIM) capacitor is a capacitor constructed with a metal top plate, a metal bottom plate, and an insulator (dielectric) sandwiched between the two metal plates.

MIM capacitors are important components in many electrical circuits, for example many analog, mixed-signal, and radio-frequency complementary metal-oxide semiconductors (RF CMOS) circuits. MIM capacitors typically provide better performance than alternatives, such as POP (poly-oxide-poly) capacitors and MOM (metal-oxide-metal lateral flux) capacitors, due to lower resistance, better matching for analog circuits (e.g., matching device characteristics such as resistance and capacitance), and/or better signal/noise ratio.

MIM capacitors are typically constructed between two interconnect metal layers, referred to as metal layers Mₓ and Mₓ₊₁, for example, using an existing metal layer Mₓ as the bottom plate (bottom electrode), constructing a top plate (top electrode) with a different metal (e.g., titanium/titanium nitride (Ti/TiN), tantalum/tantalum nitride (Ta/TaN), or tungsten (W)), and connecting an overlying metal layer Mₓ₊₁ (e.g., top metal layer) to the top and bottom plates by respective vias. The top plate typically has a higher resistance then than bottom plate, e.g., because the top plate may be limited by thickness constraints and the material of choice, thus limiting the performance of conventional MIM capacitors.

FIG. 1 shows a side cross-sectional view of an example conventional MIM capacitor 100 built on a copper (Cu) interconnect. MIM capacitor 100 includes an insulator layer 112 formed between (a) a Cu bottom plate 114 formed in a metal layer Mₓ and (b) a metal top plate 116, e.g., comprising tantalum (Ta), tantalum nitride (TaN), or titanium nitride (TiN)). A top plate cap 118, e.g., comprising silicon nitride (SiN), may be formed over the metal top plate 116. At least one photomask layer is used to form the metal top plate 116, for example to provide a location to contact the bottom plate 114, e.g., by the contact via(s) 126 discussed below.

The Cu bottom plate 114 and metal top plate 116 are each connected to a respective top metal connection pad 120, 122 formed in a metal layer Mₓ₊₁ by one or more respective vias 124, 126, for example by filling respective via holes with copper or other suitable metal. A dielectric barrier layer 130 may be formed over the top metal connection pads 120 and 122. Insulator layer 112 also acts as a dielectric diffusion barrier for the copper of bottom plate 114.

As used herein, a “via” refers to a conductive via formed by plugging or otherwise depositing a conductive material in a via hole having a small diameter or width, e.g., a diameter or width below 1 μm, and thus having a relatively large resistance, e.g., a resistance of at least 1 ohm per via. For example, conventional vias (e.g., contact vias 124 and 126 shown in FIGS. 1 and 2E) typically have a small diameter in the range of 0.1 μm to 0.5 μm, and may have a resistance of about 10 ohms/via, for example, especially for vias formed from tungsten or other highly resistive material. Thus, conventional MIM capacitors often include multiple vias (e.g., multiple vias between the top plate and top plate connection pad and/or multiple vias between the bottom plate and bottom plate connection pad) to reduce the overall resistance to some extent.

Conventional MIM capacitors, such as MIM capacitor 100 for example, are typically expensive to build, e.g., as compared with other certain types of capacitors. For example, MIM capacitors typically require additional mask layers and many additional process steps. In addition, conventional MIM capacitors, e.g., MIM capacitor 100, typically require relatively large areas of silicon, resulting in inefficient area usage, particularly with large MIM capacitors. Further, in a conventional MIM capacitor, the top plate is thin and thus provides a high series resistance, as the vertical thickness of the top plate is limited by the vertical distance between the adjacent metal layers in which the MIM capacitor is formed (e.g., between metal layers Mₓ and Mₓ₊₁.).

There is a need for MIM capacitors that can be manufactured at lower cost, with fewer or no added mask layers (e.g., as compared with a background integrated circuit manufacturing process) and/or more efficient spatial construction.

### SUMMARY

Examples of the present disclosure provide a three-dimensional (3D) MIM capacitor formed in an integrated circuit structure, and methods of forming such MIM capacitor. In some examples the MIM capacitor is formed concurrently with an interconnect structure using components of shared material layers. The interconnect structure may include a lower interconnect element, an upper interconnect element, and interconnect vias connected between the lower and upper interconnect elements. The MIM capacitor may include (a) a bottom electrode including a bottom electrode plate and a bottom electrode cup, (b) an insulator cup formed on the bottom electrode cup, (c) a top electrode formed in an opening defined by the insulator cup, (d) a dielectric etch stop layer covering the bottom electrode cup, insulator cup, and top electrode, and (e) a top electrode connection pad connected to the top electrode. The lower interconnect element and the bottom electrode plate of the MIM capacitor may be formed concurrently in the lower metal layer (Mₓ). The upper interconnect element, and the top electrode connection pad of the MIM capacitor may be formed concurrently in the upper metal layer (Mₓ₊₁). The interconnect vias, along with the bottom electrode cup, insulator cup, and top electrode of the MIM capacitor may be formed concurrently in a via layer between the lower and upper metal layers.

In some examples, the MIM capacitor may be formed without adding any photomask processes to the background manufacturing process for the relevant integrated circuit device. For example, in some examples the bottom electrode cup, the insulator cup, and top electrode may be formed in a tub opening using a damascene process.

One aspect provides a method of forming an MIM capacitor in an integrated circuit structure. A bottom electrode plate is formed in the lower metal layer (Mₓ). A dielectric layer is deposited over the bottom electrode plate, and patterned and etched to form (a) a tub opening over the bottom electrode plate, and (b) a bottom electrode via opening. A conformal fill metal (e.g., tungsten or other material suitable to form a conformal layer) is deposited in the tub opening and the bottom electrode via opening. An insulator layer is deposited over the conformal fill metal in the tub opening, followed by deposition of a top electrode layer over the insulator layer and extending into the tub opening. A chemical mechanical planarization (CMP) process is performed to remove upper portions of the top electrode layer, upper portions of the insulator layer, and upper portions of the metal fill material, such that (a) a portion of the metal fill material in the tub opening defines a bottom electrode cup, (b) a portion of the metal fill material in the bottom electrode via opening defines a bottom electrode via, (c) a portion of the insulator layer in the tub opening defines an insulator cup, and (d) a portion of the top electrode layer in the tub opening defines a top electrode. After the CMP process, a top electrode connection pad and a bottom electrode connection pad are formed in the upper metal layer. The bottom electrode connection pad is conductively connected to the bottom electrode cup through the bottom electrode via.

In one example, forming the bottom electrode plate in the lower metal layer comprises forming a metal silicide on a polysilicon region. Further, in some examples the top electrode connection pad is formed by a damascene process.

In another example, the lower metal layer comprises a metal interconnect layer.

In one example, depositing the conductive material comprises depositing a conformal fill metal between the lower metal layer and upper metal layer.

In one example, after forming the tub opening, the bottom electrode cup, the insulator cup, and the top electrode are formed without using any photomasks.

In one example, after the CMP process and before forming the top electrode connection pad in the upper metal layer, an etch stop layer is deposited over the bottom electrode cup, the insulator cup, and the top electrode.

In one example, the bottom electrode via opening is laterally spaced apart from the tub opening. In another example, the bottom electrode via opening is a laterally elongated opening extending laterally from the tub opening.

Another aspect provides a method of forming an integrated circuit structure including an MIM capacitor and an interconnect structure. A lower interconnect element and a bottom electrode plate are formed in the lower metal layer (Mx). A dielectric layer is deposited over the lower interconnect element and bottom electrode plate, and patterned and etched to form (a) a plurality of interconnect via openings over the lower interconnect element, (b) a tub opening over the bottom electrode plate, and (c) a bottom electrode via opening. A via fill metal, e.g., tungsten, is conformally deposited into the plurality of interconnect via openings, the tub opening, and the bottom electrode via opening. An insulator layer is deposited over the via fill metal in the tub opening. A top electrode layer is deposited over the insulator layer and extends into the tub opening. A CMP process is then performed to remove upper portions of the top electrode layer, insulator layer, and via fill material, such that (a) a portion of the via fill metal in each interconnect via opening defines an interconnect via, (b) a portion of the via fill metal in the tub opening defines a bottom electrode cup, (c) a portion of the vial layer in the bottom electrode via opening defines a bottom electrode via, (d) a portion of the insulator layer in the tub opening defines an insulator cup, and (e) a portion of the top electrode layer in the tub opening defines a top electrode. After the CMP process, an upper interconnect element, a top electrode connection pad, and a bottom electrode connection pad are formed in the upper metal layer above the lower metal layer. The bottom electrode connection pad is conductively connected to the bottom electrode cup through the bottom electrode via.

In one example, the lower metal layer comprises a silicided polysilicon layer, wherein the lower interconnect element comprises a first metal silicide region on a first polysilicon region and the bottom electrode plate comprises a second metal silicide region on a second polysilicon region.

In one example, the upper interconnect element, the top electrode connection pad, and the bottom electrode are formed by a damascene process.

In one example, the lower metal layer comprises a first metal interconnect layer (i.e., metal-1 layer).

In one example, after forming the tub opening, the bottom electrode cup, the insulator cup, and the top electrode are formed without using any photomasks.

In one example, after the CMP process and before forming the top electrode connection pad and the bottom electrode connection pad in the upper metal layer, an etch stop layer is deposited over the bottom electrode cup, the bottom electrode via, the insulator cup, and the top electrode.

Another aspect provides an integrated circuit structure including an MIM capacitor having (a) a bottom electrode including (i) a bottom electrode plate and (ii) a bottom electrode cup formed from a conformal fill metal, (b) an insulator cup formed on the bottom electrode cup, (c) a top electrode formed in an opening defined by the insulator cup, and (d) a top electrode connection pad connected to the top electrode.

In one example, the integrated circuit structure further includes an interconnect structure including a lower interconnect element, an upper interconnect element, and an interconnect via between the lower interconnect element and the upper interconnect element, wherein the bottom electrode cup and the interconnect via are formed in a common via layer from the conformal fill metal.

In one example, the lower interconnect element and the bottom electrode plate are formed in a lower metal layer, and the upper interconnect element and the top electrode connection pad are formed in an upper metal layer.

In one example, the lower metal layer comprises a silicide polysilicon layer, and the upper metal layer comprises a damascene metal layer.

In one example, the lower interconnect element and the bottom electrode plate are formed in a lower metal layer, and the upper interconnect element and the top electrode connection pad are formed in an upper metal layer above the lower metal layer. The bottom electrode cup, the insulator cup, and the top electrode may be formed between the lower metal layer and upper metal layer, e.g., in a tub opening formed in a via layer between the lower metal layer and upper metal layer.

In one example, the integrated circuit structure further includes a bottom electrode via and a bottom electrode connection pad connected to the bottom electrode via. The bottom electrode connection pad is conductively connected to the bottom electrode cup through the bottom electrode via, and the bottom electrode cup and the bottom electrode via are formed from the conformal fill metal.

In one example, bottom electrode via is laterally spaced apart from the bottom electrode cup. In another example, the bottom electrode via comprises a laterally elongated via extending laterally from the bottom electrode cup.

### BRIEF DESCRIPTION OF THE DRAWINGS

Example aspects of the present disclosure are described below in conjunction with the figures, in which:

FIG. 1 shows a side cross-sectional view of an example conventional MIM capacitor built on a copper (Cu) interconnect;

FIGS. 2A and 2B show a top view and a side cross-sectional view, respectively, of an example integrated circuit structure including an interconnect structure and an MIM capacitor formed concurrently using shared material layers, according to one example;

FIGS. 3A and 3B show a top view and a side cross-sectional view, respectively, of an example integrated circuit structure including the MIM capacitor shown in FIGS. 2A and 2B, according to one example;

FIGS. 4A-4H are a series of side cross-sectional views showing an example process for forming the example integrated circuit structure shown in FIGS. 2A and 2B, according to one example;

FIG. 5 shows a side cross-sectional view of an example integrated circuit structure including an interconnect structure and an MIM capacitor formed on an aluminum interconnect layer, according to one example; and

FIG. 6 shows a side cross-sectional view of an example integrated circuit structure including an interconnect structure and an MIM capacitor formed on copper damascene elements, according to one example.

FIGS. 7A and 7B show a top view and a side cross-sectional view, respectively, of an example MIM capacitor including a laterally elongated bottom contact via extending from a bottom electrode cup of the MIM capacitor, according to one example;

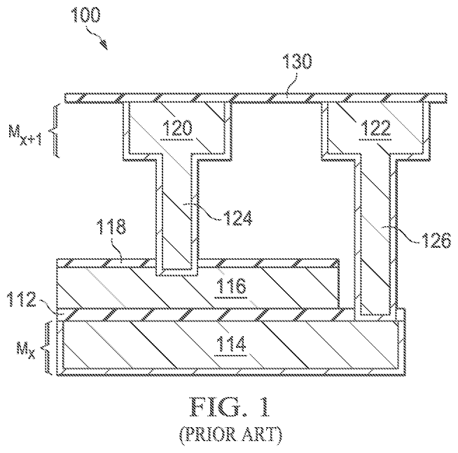

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

The present disclosure provides for a three-dimensional (3D) MIM capacitor formed in an integrated circuit structure, and methods of forming such MIM capacitor. In some examples, the MIM capacitor may be formed without adding any photomask or photomask process, as compared with a background integrated circuit manufacturing process. In some examples the MIM capacitor is formed concurrently with an interconnect structure using components of shared material layers. The interconnect structure may include a lower interconnect element, an upper interconnect element, and a plurality of interconnect vias between the lower and upper interconnect layers. The MIM capacitor may include (a) a bottom electrode including a bottom electrode plate and a bottom electrode cup, (b) an insulator cup formed on the bottom electrode cup, (c) a top electrode formed in an opening defined by the insulator cup, (d) a dielectric etch stop layer covering the bottom electrode cup, insulator cup, and top electrode, and (e) a top electrode connection pad connected to the top electrode. The lower interconnect element and the bottom electrode plate of the MIM capacitor may be formed concurrently in the lower metal layer Mₓ. The upper interconnect element and the top electrode connection pad of the MIM capacitor may be formed in an upper metal layer Mₓ₊₁. The interconnect vias, and the bottom electrode cup insulator cup, and top electrode, and bottom electrode via may be formed concurrently in a via layer between the lower and upper metal layers, e.g., using a damascene process.

As used herein, a “metal layer,” for example in the context of the lower metal layer Mₓ or upper metal layer Mₓ₊₁, may comprise any metal or metalized layer or layers, including (a) a metal interconnect layer, e.g., comprising copper, aluminum or other metal deposited by a subtractive patterning process (e.g., deposition, patterning, and etching of a metal layer) or using a damascene process, or (b) a silicide polysilicon layer including a number of polysilicon regions each having a layer or region of metal silicide formed thereon, or (c) any other patterned layer including at least one metal structure defining at least one component of a MIM capacitor. For example, in some examples the lower metal layer Mₓ may be a silicided polysilicon layer and the upper metal layer Mₓ₊₁ may comprise a first metal interconnect layer, often referred to as metal-1. In such examples, x=0 such that the lower metal layer Mₓ=M₀ and the upper metal layer Mₓ₊₁=M₁ (i.e., metal-1). Further, as used herein, an “interconnect structure,” e.g., in the context of the interconnect structures 204, 504, 604, and 704 disclosed herein, may include any type or types of metal layers as defined above.

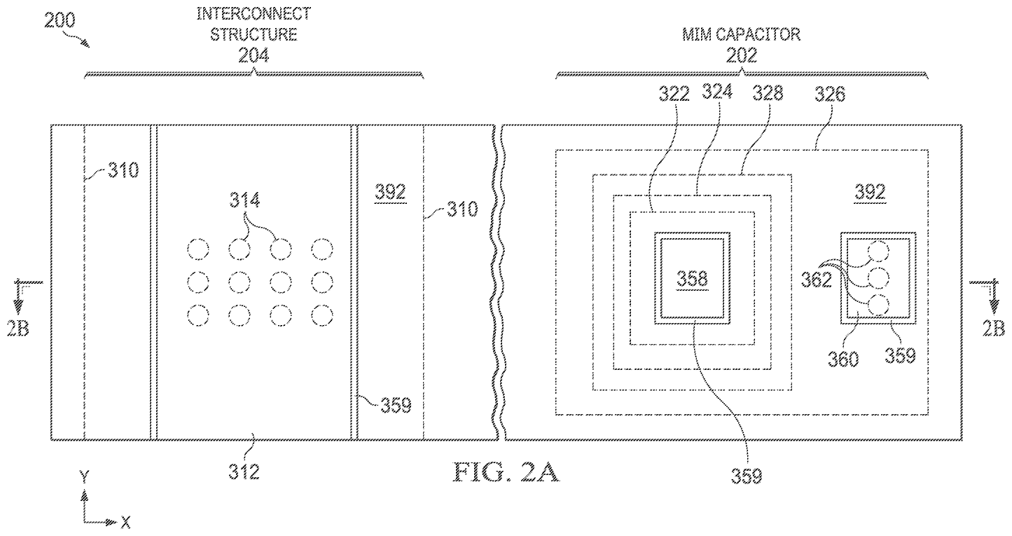

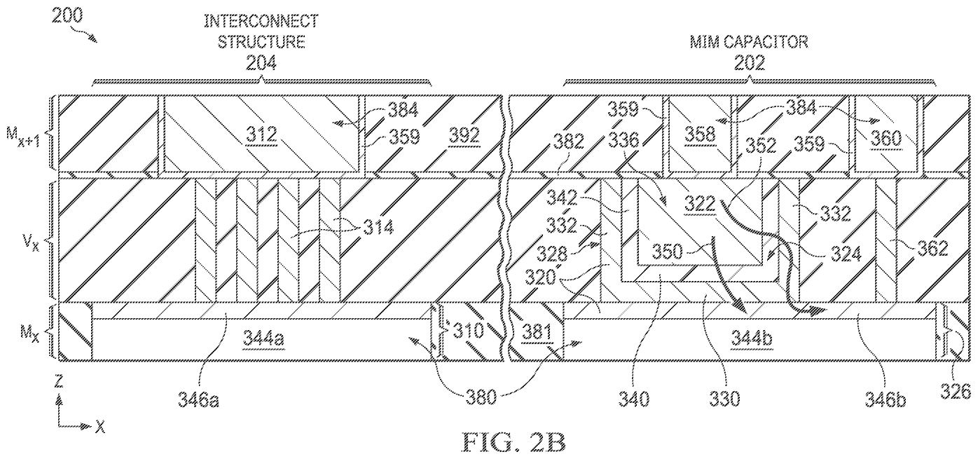

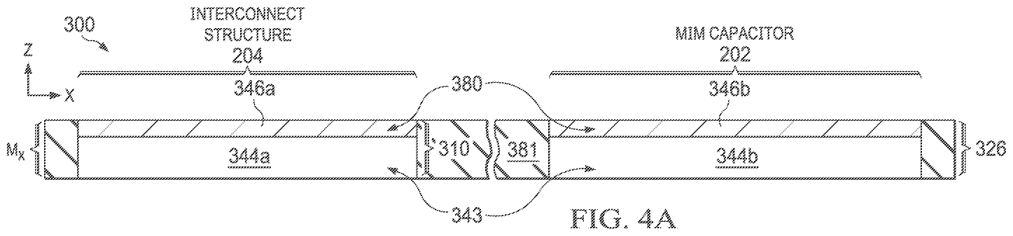

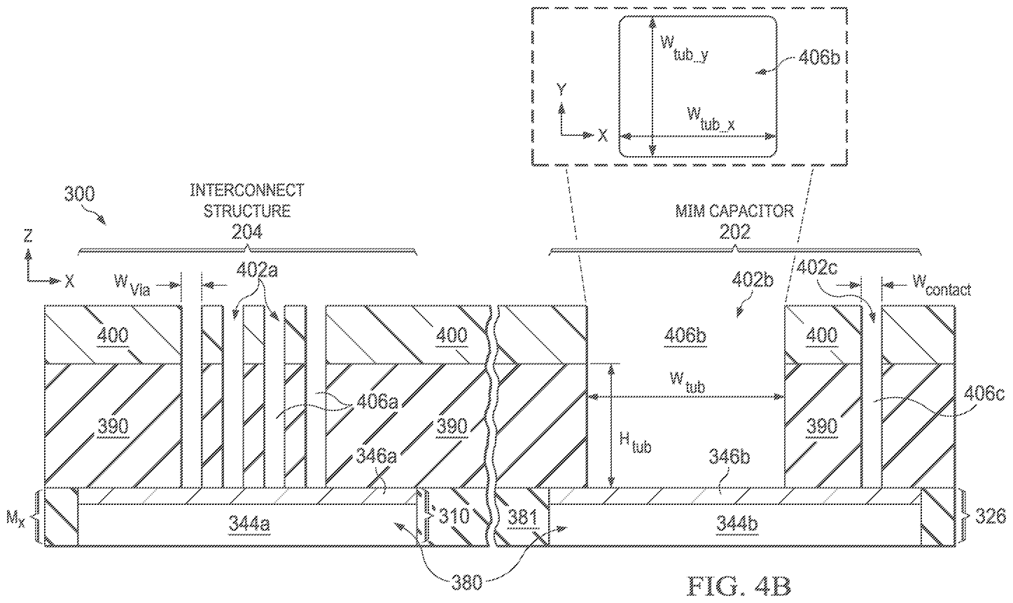

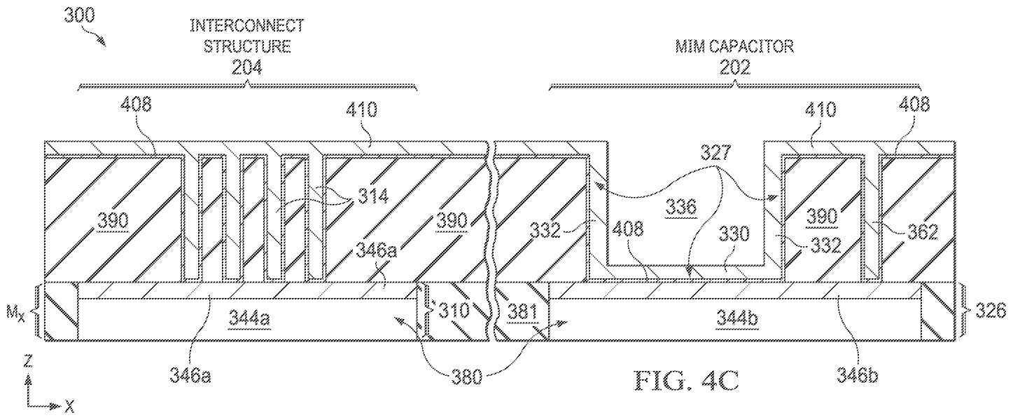

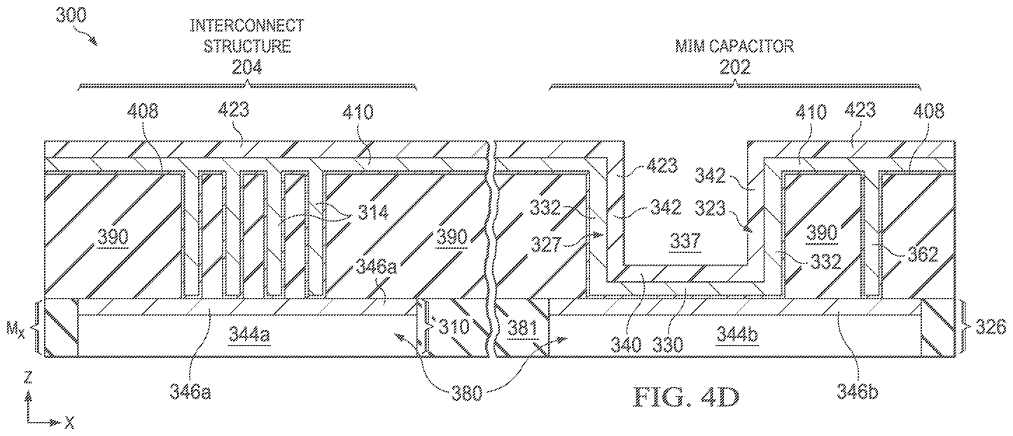

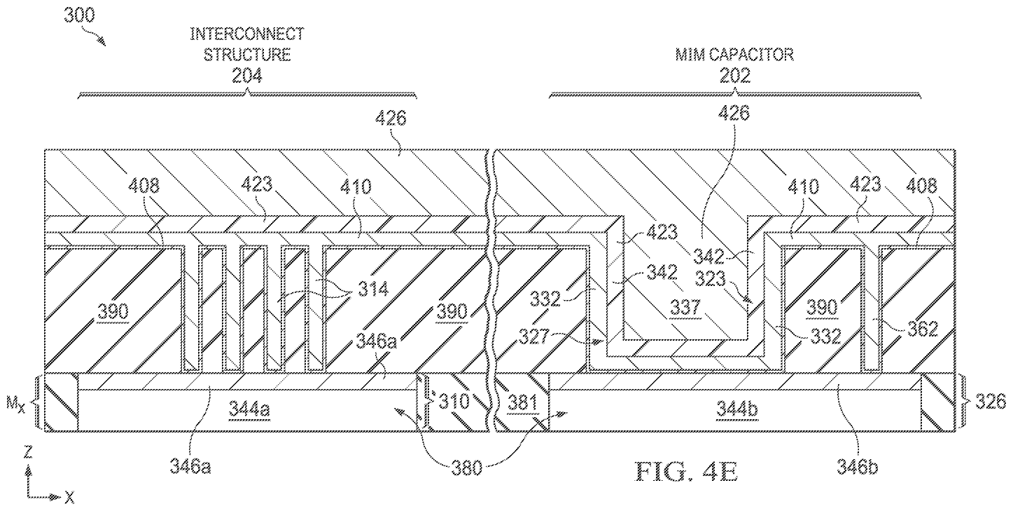

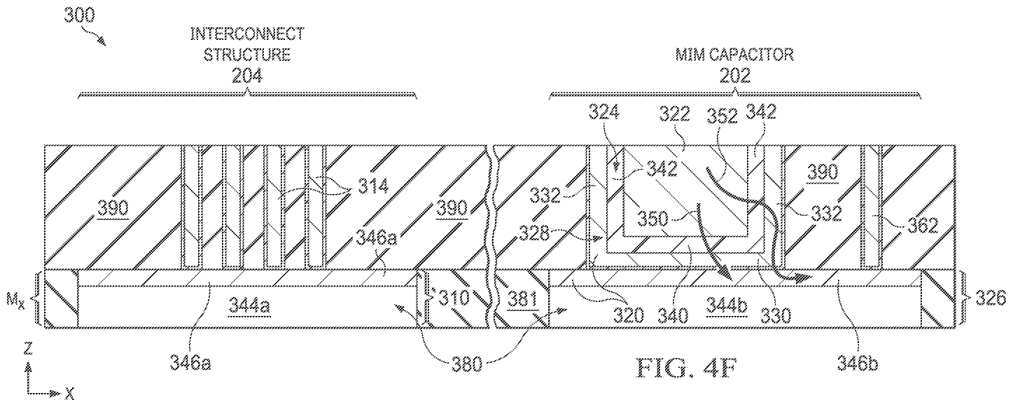

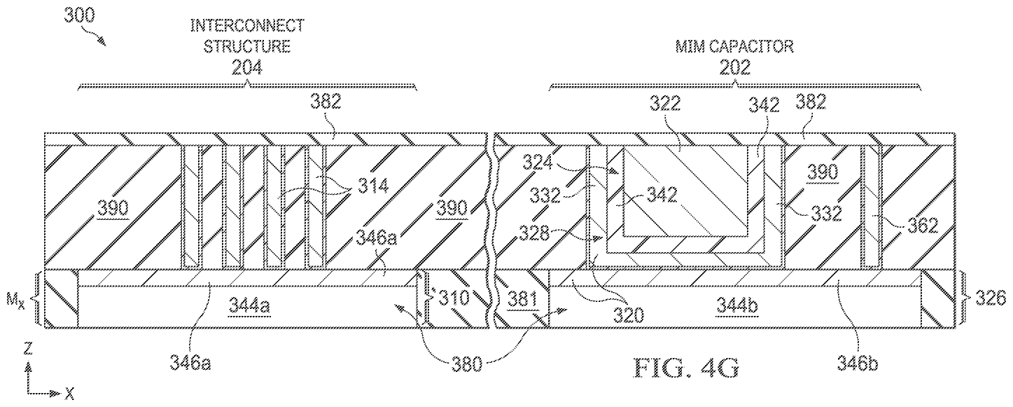

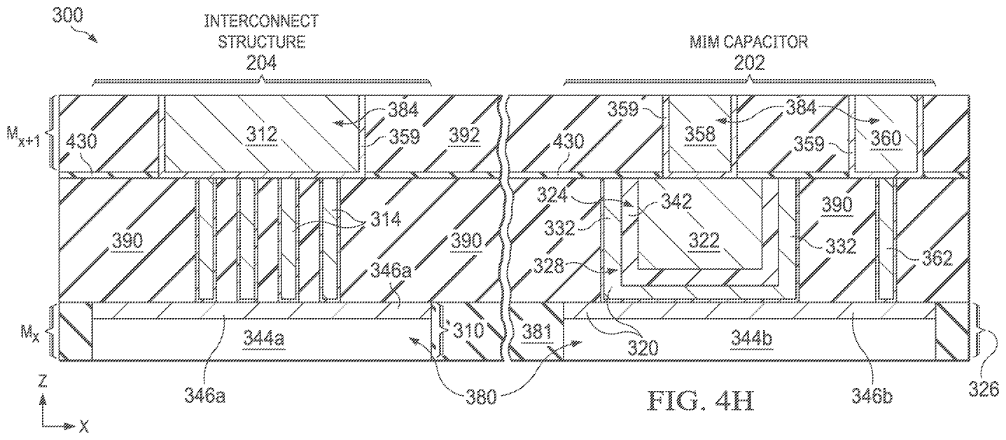

FIGS. 2A and 2B collectively show an example integrated circuit structure 200 including a MIM capacitor 202 and an interconnect structure 204 formed concurrently, according to one example. In particular, FIG. 2A shows a top view of integrated circuit structure 200, and FIG. 2B shows a cross-sectional side view taken through line 2B-2B shown in FIG. 2A. As discussed below with reference to FIGS. 4A-4G, in one example the MIM capacitor 202 may be constructed without adding any mask operations to the background integrated circuit fabrication process.

As shown in FIGS. 2A-2B, the interconnect structure 204 may include a lower interconnect element 310 formed in a lower metal layer Mₓ (for example, where x=0 for a silicided polysilicon layer as discussed above) and an upper interconnect element 312, e.g., metal-1 layer, formed in an upper metal layer Mₓ₊₁ and connected to the lower interconnect element 310 by at least one interconnect via 314 formed in a via layer Vₓ by depositing a conformal via material, e.g., tungsten, into respective via openings.

Each of the lower interconnect element 310 and upper interconnect element 312 may comprise a wire or other laterally elongated structure, or a discrete pad (e.g., having a square or substantially square shape from a top view), or any other suitable shape and structure.

The MIM capacitor 202 includes a bottom electrode 320, a top electrode 322, and an insulator cup 324 sandwiched between the bottom electrode 320 and top electrode 322. The MIM bottom electrode 320 includes (a) a bottom electrode plate 326 formed in the lower metal layer Mₓ and (b) a bottom electrode cup 328 formed on the bottom electrode plate 326. The bottom electrode plate 326 is formed in the lower metal layer Mₓ, e.g., as discussed below in more detail.

Lower interconnect element 310 comprises a first metal silicide region 346a formed on a first polysilicon region 344a, and bottom electrode plate 326 comprises a second metal silicide region 346b formed on a second polysilicon region 344b. The bottom electrode cup 328 is formed on the bottom electrode plate 326 and includes (a) a laterally-extending bottom electrode cup base 330 and (b) multiple vertically-extending bottom electrode cup sidewalls 332 extending upwardly from the laterally-extending bottom electrode cup base 330. The bottom electrode cup 328 may formed concurrently with the at least one interconnect via 314 by depositing the conformal via material, e.g., tungsten, into a tub opening formed in the via layer Vₓ.

The bottom electrode cup base 330 may have a rectangular perimeter (e.g., having a square or non-square rectangular shape) defining four lateral sides when viewed from above, with four vertically-extending bottom electrode cup sidewalls 332 extending upwardly from the four lateral sides of the rectangular perimeter, as shown in FIGS. 2A and 2B viewed collectively. In another example, the bottom electrode cup 328 may include two vertically-extending bottom electrode cup sidewalls 332 extending upwardly from two opposing lateral sides of the bottom electrode cup base 330, for example the two bottom electrode cup sidewalls 332 visible in FIG. 2B. The bottom electrode cup 328 may include any other number of vertically-extending bottom electrode cup sidewalls 332 extending upwardly from the bottom electrode cup base 330.

The laterally-extending bottom electrode cup base 330 and vertically-extending bottom electrode cup sidewalls 332 define an interior opening 336 of the bottom electrode cup 328. As shown, the insulator cup 324 is formed in the interior opening 336 of the bottom electrode cup 328 and has a cup-shape including a laterally-extending insulator cup base 340, formed over the bottom electrode cup base 330, and multiple vertically-extending insulator sidewalls 342 extending upwardly from the laterally-extending insulator cup base 340, with each vertically-extending insulator sidewall 342 formed on (laterally adjacent) a respective bottom electrode cup sidewall 332. Insulator cup 324 may comprise silicon nitride (SiN) with a thickness of about 500 Å. Alternatively, insulator cup 324 may comprise Al₂O₃, ZrO₂, HfO₂, ZrSiOₓ, HfSiOₓ, HfAlOₓ, or Ta₂O₅, or other suitable capacitor insulator material.

The top electrode 322 is formed inside the insulator cup 324, and covers the insulator cup base 340 and is laterally adjacent the multiple vertically-extending insulator sidewalls 342, so as to fill the interior opening 336. The top electrode 322 may comprise Al, Ti, TiN, W, TiW, Co, Ta, TaN, Cu, or any combination thereof, for example, TiN plus Al, TiN plus W, or a Ta/TaN bilayer plus Cu.

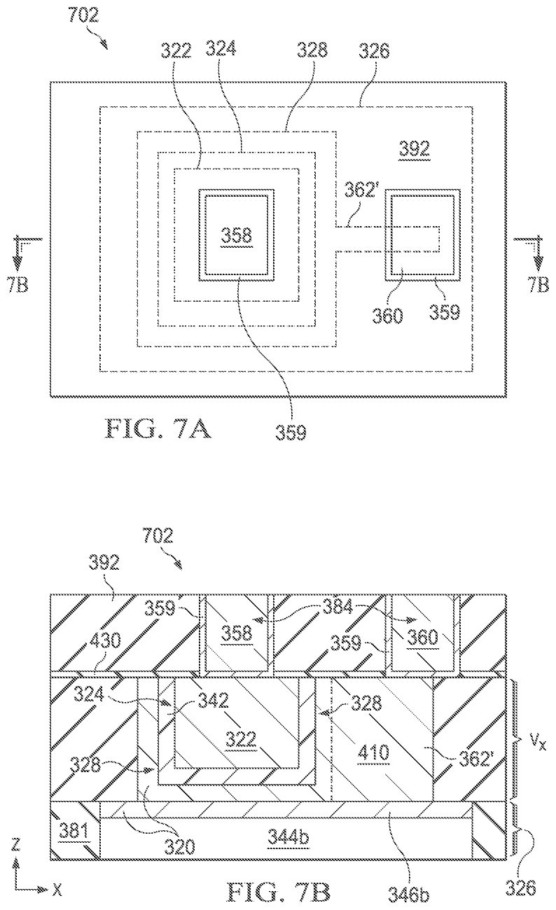

The MIM capacitor 202 also includes a top electrode connection pad 358 and a bottom electrode connection pad 360 formed in the upper metal layer Mₓ₊₁. The top electrode connection pad 358 may be formed directly on the top electrode 322. The bottom electrode connection pad 360 may be connected to the bottom electrode plate 326 by a bottom electrode via 362. In the example shown in FIGS. 2A-2B and FIGS. 4A-4H, the bottom electrode via 362 may be formed laterally spaced apart from the bottom electrode cup 328, and may have a shape and size similar to the interconnect via 314, and may comprise multiple bottom electrode vias 362. In another example, as shown in FIGS. 7A-7B discussed below, a bottom electrode via 362′ may be formed as an extension of the bottom electrode cup 328, which configuration provides a reduced electrical resistance between the bottom electrode cup 328 and the bottom electrode connection pad 360, e.g., as compared with the examples shown in FIGS. 2A-2B and FIGS. 4A-4H in which the electrical resistance between the bottom electrode cup 328 and bottom electrode connection pad 360 may be defined by the physical properties of the second metal silicide region 346b of the bottom electrode 326.

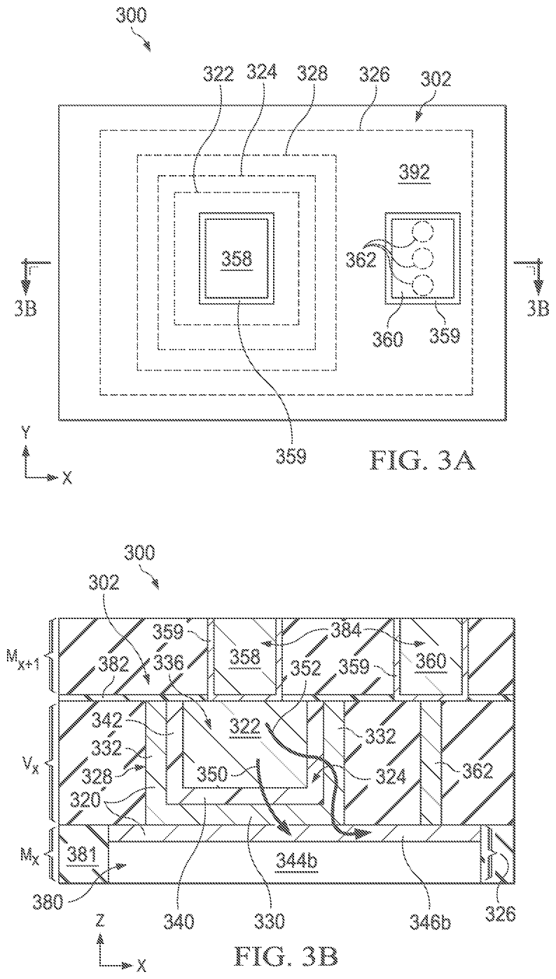

Each of the top electrode connection pad 358 and bottom electrode connection pad 360 may have any suitable shape and size. For example, each of the top electrode connection pad 358 and bottom electrode connection pad 360 may have a generally square shape in the x-y plane, e.g., as shown in the example top views shown in FIG. 2A, FIG. 3A, and FIG. 7A. In another example (not shown) each of the top electrode connection pad 358 and bottom electrode connection pad 360 may have a generally circular shape in the x-y plane. As another example, the top electrode connection pad 358 and/or bottom electrode connection pad 360 may be substantially elongated, e.g., running laterally across the wafer in the x-direction and/or the y-direction.

The top electrode 322 is capacitively coupled to both the bottom electrode cup base 330 and the bottom electrode cup sidewalls 332 of the bottom electrode cup 328 (which bottom electrode cup 328 is conductively coupled to the bottom electrode plate 326), which defines a substantially larger area of capacitive coupling between the top electrode 322 and bottom electrode 320, as compared with conventional designs. In particular, MIM capacitor 202 defines the following capacitive couplings between the top electrode 322 and bottom electrode 320:

(a) capacitive coupling between the top electrode 322 and bottom electrode 320 by a displacement current path through the insulator cup base 340 and through the bottom electrode cup base 330, as indicted by arrow 350; and

(b) capacitive coupling between the top electrode 322 and bottom electrode 320 by a displacement current path through each vertically-extending insulator sidewall 342 and through the corresponding vertically-extending bottom electrode cup sidewall 332, as indicated by arrow 352.

The laterally-extending insulator cup base 340 effectively defines a plate capacitor, with the top and bottom plates extending horizontally (x-y plane), and each vertically-extending insulator sidewall 342 effectively defines an additional plate capacitor, with the top and bottom plates extending vertically (x-z plane or y-z plane). Thus, MIM capacitor 202 may be referred to as a “three-dimensional” or “3D” MIM capacitor.

The lower interconnect element 310 of interconnect structure 204 and the bottom electrode plate 326 of the MIM capacitor 202 may each comprise a lower metal structure 380 formed concurrently in the lower metal layer Mₓ. Similarly, the upper interconnect element 312 of interconnect structure 204, and the top electrode connection pad 358 and bottom electrode connection pad 360 of the MIM capacitor 202, may each comprise an upper metal structure 384 formed concurrently in the upper metal layer Mₓ₊₁.

Each of the lower metal layer Mₓ and upper metal layer Mₓ₊₁ may comprise any metal or metalized layer or layers. For example, each of the lower metal layer Mₓ and upper metal layer Mₓ₊₁ may comprise a copper or aluminum interconnect layer, bond pad layer, or other metal layer. As another example, the lower metal layer Mₓ may be a silicided polysilicon layer (e.g., where Mₓ is M₀), as discussed below.

Lower metal structures 380 and upper metal structures 384 may be formed in the lower metal layer Mₓ and upper metal layer Mₓ₊₁, respectively, in any suitable manner, for example using a subtractive patterning process (e.g., deposition, patterning, and etching of a metal layer), or using a damascene process, or by forming a metal silicide region on patterned polysilicon regions, or any other suitable process.

In the example implementation shown in FIG. 2B, lower metal structures 380 are formed in a silicided polysilicon layer Mₓ, wherein Mₓ=M₀, and upper metal structure 384 are formed in a copper damascene layer Mₓ₊₁, wherein Mₓ₊₁=M₁. Each lower metal structure 380 formed in the silicided polysilicon layer Mₓ comprises a metal silicide region formed on a respective polysilicon region. In particular, and as described above, lower interconnect element 310 comprises a first metal silicide region 346a formed on a first polysilicon region 344a, and bottom electrode plate 326 comprises a second metal silicide region 346b formed on a second polysilicon region 344b. Upper metal structures 384 (including the upper interconnect element 312, top electrode connection pad 358, and bottom electrode connection pad 360) may comprise copper damascene elements, each formed over a barrier layer 359 (e.g., a Ta/TaN bilayer) in a respective trench in a dielectric layer 392.

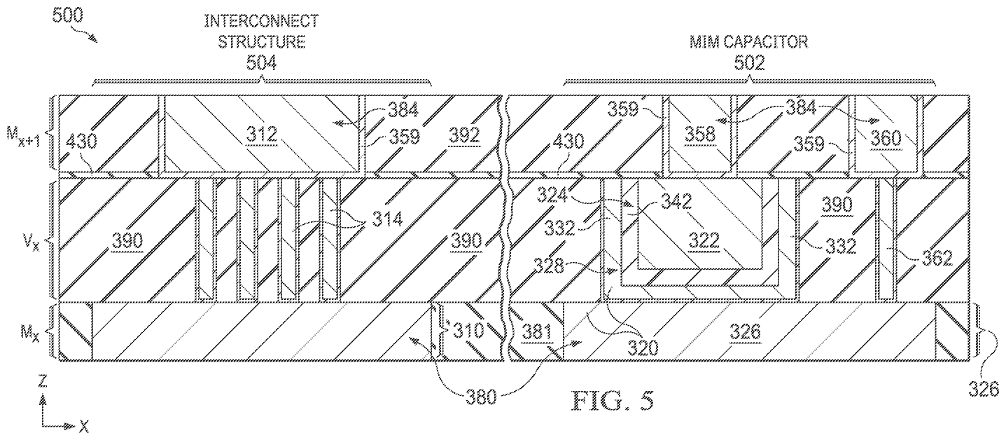

In other examples, lower metal structures 380 and upper metal structures 384 may be formed in lower metal layer Mₓ and upper metal layer Mₓ₊₁, respectively, in any other suitable manner. For example, lower metal structures 380 and upper metal structures 384 may be formed as copper damascene structures. As another example, as shown in FIG. 5 discussed below, lower metal structures 380 may be formed by subtractive patterning of the lower metal layer Mₓ (e.g., deposition, patterning, and etching of an aluminum layer), while upper metal structures 384 may be formed as copper damascene structures in the upper metal layer Mₓ₊₁.

A dielectric barrier layer 382, e.g., SiN, SiC, or a high-k dielectric material (e.g., having a dielectric constant above 7) may be formed prior to formation of the upper metal layer Mₓ₊₁ to provide an etch stop for a subsequent Mₓ₊₁ trench metal etch (for forming upper metal structures 384) and provide an effective termination layer for the edge electric field of the MIM capacitor 202 to improve the breakdown voltage of the MIM capacitor 202.

Thus, as shown in FIG. 2B and discussed herein, the bottom electrode cup 328, insulator cup 324, top electrode 322, and bottom electrode via 362, may be formed concurrently with the interconnect vias 314 in the via layer Vₓ between the lower metal layer Mₓ and upper metal layer Mₓ₊₁. For example, as shown in FIG. 4A-4G discussed below, the bottom electrode cup 328, insulator cup 324, and top electrode 322 may be formed by a damascene process including forming a tub opening 406b in an inter-metal dielectric (IMD) layer 390, depositing suitable materials for forming the bottom electrode cup 328, insulator cup 324, and top electrode 322, and performing a CMP process to remove portions of the deposited materials above the tub opening 406b.

In some embodiments, the MIM capacitor 202 discussed above may be constructed separate from the construction of interconnect structure 204 or other interconnection structures, using similar techniques as disclosed herein, e.g., as discussed below with reference to FIGS. 4A-4G, FIG. 5, FIG. 6, and/or FIGS. 7A-7B. Thus, FIGS. 2A and 2B collectively show an example integrated circuit structure 300 including the MIM capacitor 202 shown in FIGS. 3A and 3B, wherein the MIM capacitor 202 may be constructed separate from the construction of interconnect structure 204 or other interconnection structures, according to one example. In particular, FIG. 3A shows a top view of integrated circuit structure 300 including MIM capacitor 202, and FIG. 3B shows a cross-sectional side view taken through line 3B-3B shown in FIG. 3A. As discussed below with reference to 4A-4G, in one example the MIM capacitor 202 may be constructed without adding any mask operations to the background integrated circuit fabrication process.

FIGS. 4A-4G show cross-sectional views illustrating an example process for forming the example integrated circuit structure 200 shown in FIGS. 2A-2B, including MIM capacitor 202 and nearby interconnect structure 204, according to one example. Each FIG. 4A-4G shows cross-sectional views at two locations of an integrated circuit structure under construction, namely a first location (labelled “202: MIM Capacitor”) at which MIM capacitor 202 is formed and a second location (labelled “204: Interconnect Structure”) at which interconnect structure 204 is formed.

First, as shown in FIG. 4A, the lower metal structures 380, including the lower interconnect element 310 of interconnect structure 204 and the bottom electrode plate 326 of MIM capacitor 202, are formed in the lower metal layer Mₓ. In particular, a polysilicon layer 343 is deposited, patterned, and etched to form the first polysilicon region 344a and second polysilicon region 344b. A self-aligned silicide (salicide) process may be performed to form the first metal silicide region 346a on the first polysilicon region 344a and the second metal silicide region 346b on the second polysilicon region 344b. The first and second metal silicide regions 346a and 346b may comprise titanium silicide, cobalt silicide, nickel silicide, or other silicide having a thickness in the range of 100-500 Å. Although the first and second metal silicide regions 346a and 346b may be very thin compared with the underlying first and second polysilicon region 344a and 344b, the silicided polysilicon layer (including lower interconnect element 310 and bottom electrode plate 326) defines a lower metal layer Mₓ for the purposes of the present disclosure. In this example, the silicided polysilicon layer Mₓ may define a lower metal layer M₀ (where x=0) below a first metal interconnect layer M₁ (where Mₓ₊₁=M₁), often referred to as the metal-1 layer.

Next, as shown in FIG. 4B an inter-metal dielectric (IMD) layer 390 may be deposited on the structure 200 and planarized by a CMP process, followed by deposition and patterning of a photoresist layer 400 over the IMD layer 390. IMD layer 390 may include one or more dielectric materials, e.g., at least one of silicon oxide, PSG (phosphosilicate glass), FSG (fluorine doped glass), OSG (organosilicate glass), porous OSG, or other low-k dielectric material, e.g., having a dielectric constant less than 3.6. The photoresist layer 400 may be deposited on the IMD layer 390 and patterned to simultaneously define various mask openings 402a-402c, including interconnect via mask openings 402a, a tub mask opening 402b, and a bottom electrode via mask opening 402c.

The IMD layer 390 may be etched through the mask openings 402a-402c to concurrently form corresponding IMD openings 406a-406c, including (a) interconnect via openings 406a for forming interconnect vias 314, (b) a tub opening 406b for forming the bottom electrode cup 328, the insulator cup 324, and the top electrode 322, (c) and a bottom electrode via opening 406c for forming the bottom electrode via 362. IMD openings 406a-406c may be formed using a plasma etch or other suitable etch, followed by a resist strip or other suitable process to remove remaining portions of photoresist layer 400.

With respect to interconnect structure 204, the interconnect via openings 406a may be via openings having a width (or diameter or Critical Dimension (CD)) Wᵥᵢₐ in both the x-direction and y-direction in the range of 0.1-0.5 μm, for example. The interconnect width Wᵥᵢₐ may significantly affect the performance of the IC device being formed.

With respect to MIM capacitor 202, the bottom electrode via opening 406c may be formed as a via opening with a width (or diameter or Critical Dimension (CD)) W_{contact}. In some examples, the bottom electrode via opening 406c is formed the same as each of the interconnect via openings 406a, thus Wᵥᵢₐ=W_{contact}, and may have similar dimensions in both the x-direction and y-direction. In contrast, tub opening 406b may have a substantially width in the x-direction (W_{tub_x}) and/or y-direction (W_{tub_y}) than interconnect via openings 406a and the bottom electrode via opening 406c. The shape and dimensions of the tub opening 406b may be selected based on various parameters, e.g., for effective manufacturing of the MIM capacitor 202 (e.g., effective deposition of the top plate material (e.g., aluminum) into the tub opening 406b) and/or for desired performance characteristics of the resulting MIM capacitor 202. In one example, the tub opening 406b may have a square or rectangular shape from the top view. In other examples, tub opening 406b may have a circular or oval shape from the top view.

As noted above, a width of tub opening 406b in the x-direction (W_{tub_x}), y-direction (W_{tub_y}), or both the x-direction and y-direction (W_{tub_x} and W_{tub_y}) may be substantially larger than the width W_{Via} of via openings 406a in the x-direction, y-direction, or both the x-direction and y-direction. For example, in some examples, each width of W_{tub_x} and W_{tub_y} of tub opening 406b is at least twice as large as the width W_{Via} of via openings 406a. In particular examples, each width of W_{tub_x} and W_{tub_y} of tub opening 406b is at least five time as large as the width W_{Via} of via openings 406a. In some examples, W_{tub_x} and W_{tub_y} are each in the range of 1-100 μm.

Further, tub opening 406b may be formed with a height-to-width aspect ratio of less than or equal to 2.0 in both the x-direction and y-direction, e.g., to allow effective filling of the tub opening 406b by conformal materials. For example, tub opening 406b may be formed with aspect ratios H_{tub}/W_{tub_x} and H_{tub}/W_{tub_y} each in the range of 0.1-2.0, for example in the range of 0.5-2.0. In some examples, aspect ratios H_{tub}/W_{tub_x} and H_{tub}/W_{tub_y} are each less than or equal to 1.5, e.g., for effective filling of tub opening 406b by conformal materials, e.g., tungsten. For example, tub opening 406b may be formed with aspect ratios H_{tub}/W_{tub_x} and H_{tub}/W_{tub_y} each in the range of 0.5-1.5, or more particularly in the range of 0.8-1.2.

Although the bottom electrode via opening 406c shown in FIG. 4B may have a similar shape and size as each of the interconnect via openings 406a, in other examples the bottom electrode via opening 406c may comprise a larger opening, for example elongated in the x-direction and/or y-direction as compared with the via openings having Wᵥᵢₐ. For example, the bottom electrode via opening 406c may comprise an extension of the tub opening 406b configured to form a laterally elongated (in the x-direction) bottom electrode via 362, which may be referred to as a rectangular via or “slotted via,” that directly connects the bottom electrode cup 328 with the bottom electrode connection pad 360. FIGS. 7A-7B discussed below illustrate one example of such implementation.

Next, as shown in FIG. 4C, a TiN liner 408 is deposited over the IMD layer 390 and extends down into the IMD openings 406a-406c, followed by deposition of a conformal fill metal 410, for example tungsten or other metal suitable for conformal deposition, which also extends down into the IMD openings 406a-406c. As shown, the deposited via fill metal 410 (a) fills interconnect via openings 406a to form interconnect vias 314, (b) covers the interior surfaces of the tub opening 406b to form a cup-shaped bottom electrode region 327 defining interior opening 336, (c) and fills the bottom electrode via opening 406c to form the bottom electrode via 362. As discussed above, the cup-shaped bottom electrode region 327 includes multiple vertically-extending bottom electrode cup sidewalls 332 extending upwardly from the laterally-extending bottom electrode cup base 330. In one example, the via fill metal 410 comprises tungsten deposited with a thickness of 1000 Å to 5000 Å. In other examples, the via fill metal 410 may comprise Al, Co, or TiN. The via fill metal 410 may be deposited by a conformal chemical vapor deposition (CVD) process or other suitable deposition process.

Next, as shown in FIG. 4D, an insulator layer 423, e.g., a silicon nitride (SiN) layer with a thickness of about 500 Å, is deposited over the via fill metal 410 and extends down into the interior opening 336 of the cup-shaped bottom electrode region 327 (shown in FIG. 4C) to define a cup-shaped insulator region 323 defining an interior opening 337. In other examples, the insulator layer 423 may comprise high-k dielectric materials, for example Al₂O₃, ZrO₂, HfO₂, ZrSiOₓ, HfSiOₓ, HfAlOₓ, or Ta₂O₅, or other suitable capacitor insulator material.

Next, as shown in FIG. 4E, a top electrode layer 426 is deposited over the insulator layer 423 and fills the interior opening 337 of the cup-shaped insulator region 323. The top electrode layer 426 may comprise Al, Ti, TiN, W, TiW, Co, Ta, TaN, Cu, or any combination thereof.

Next, as shown in FIG. 4F, a chemical mechanical planarization (CMP) process is performed to remove upper portions of the top electrode layer 426, insulator layer 423, via fill metal 410, and liner 408 to define (a) the top electrode 322 from remaining portions of the top electrode layer 426, (b) the insulator cup 324 from remaining portions of the cup-shaped insulator region 323, and (c) the bottom electrode cup 328 from remaining portions of the cup-shaped bottom electrode region 327.

As discussed above with reference to FIGS. 2A-2B, the insulator cup 324 and the bottom electrode plate 326 collectively define the bottom electrode 320. Further, as discussed above, MIM capacitor 202 defines the following capacitive couplings between the top electrode 322 and bottom electrode 320:

(a) capacitive coupling between the top electrode 322 and bottom electrode 320 by a displacement current path through the insulator cup base 340 and through the bottom electrode cup base 330, as indicted by arrow 350; and

(b) capacitive coupling between the top electrode 322 and bottom electrode 320 by a displacement current path through each vertically-extending insulator sidewall 342 and through the corresponding vertically-extending bottom electrode cup sidewall 332, as indicated by arrow 352.

Next, as shown in FIG. 4G, an etch stop layer 382 is deposited on the structure 200. The etch stop layer 382 may comprise SiN, SiC, or a high-k dielectric material (e.g., having a dielectric constant greater than 7). The etch stop layer 382 may provide an etch stop for a damascene process etch for forming the upper metal layer Mₓ₊₁, as discussed below. The etch stop layer 382 may also terminate the edge of the electric field of the MIM capacitor 202, which may relieve edge electric field crowding to help provide a high breakdown voltage. The etch stop layer 382 may also act as a dielectric diffusion barrier, e.g., if the top electrode 322 is formed from copper.

Finally, as shown in FIG. 4H, the upper metal layer Mₓ₊₁ is formed with discrete upper metal structures 384, including the upper interconnect element 312 of interconnect structure 204, and the top electrode connection pad 358 and bottom electrode connection pad 360 of MIM capacitor 202, using a single damascene process. This single damascene process may include depositing dielectric layer 392, forming a metal layer trench by patterning and etching, depositing a copper diffusion barrier layer (typically Ta, TaN, or a bi-layer of both) followed by a copper seed layer in the damascene trenches, depositing a metal 394 to fill the damascene trenches, performing an anneal, and finally a chemical mechanical planarization (CMP) process to remove portions of the metal 394 above the dielectric layer 392 and define the discrete upper metal structures 384. The dielectric layer 392 may comprise comprising silicon oxide (SiO₂), fluorosilicate glass (FSG), organosilicate glass (OSG), porous OSG, or other suitable dielectric material. The metal 394 may comprise copper, which may be deposited using an electro-chemical plating process.

After forming upper metal structures 384 in upper metal layer Mₓ₊₁, the process may continue with additional interconnect construction.

FIG. 5 shows a side cross-sectional view of an example integrated circuit structure 500 including a MIM capacitor 502 and nearby interconnect structure 504 formed concurrently. Integrated circuit structure 500 is similar to integrated circuit structure 200 discussed above, except lower metal structures 380 formed in the lower metal layer Mₓ (including lower interconnect element 310 and bottom electrode plate 326) are formed from aluminum using a subtractive patterning process, including deposition, patterning, and etching of an aluminum layer.

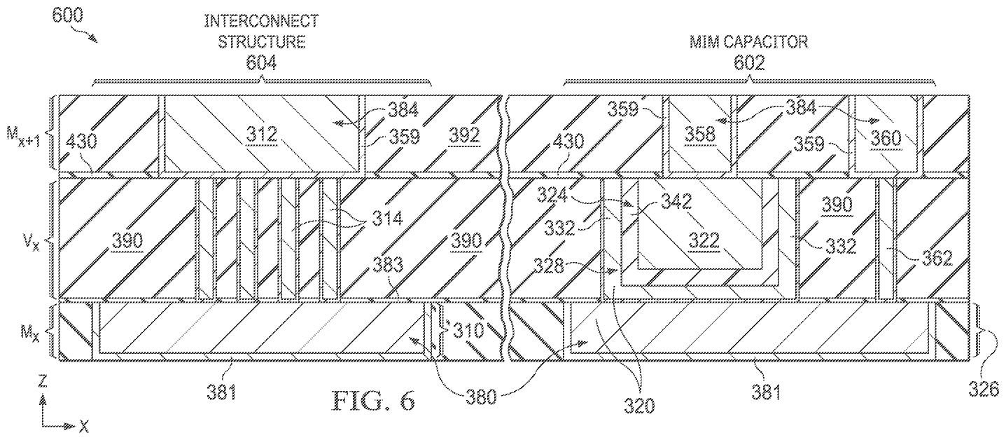

FIG. 6 shows a side cross-sectional view of another example integrated circuit structure 600 including a MIM capacitor 602 and nearby interconnect structure 604 formed concurrently. Integrated circuit structure 600 is similar to integrated circuit structure 200 discussed above, except lower metal structures 380 formed in the lower metal layer Mₓ (including lower interconnect element 310 and MIM bottom electrode plate 326) comprise copper damascene structures, each formed over a barrier layer 381 (e.g., a Ta/TaN bilayer) in a respective trench, followed by deposition of a dielectric barrier layer 383, e.g., comprising SiN or SiC, over the copper damascene structures 380.

FIGS. 7A and 7B show a top view and a side cross-sectional side view, respectively, of an example MIM capacitor 702 that may be formed in integrated circuit structure 200, in place of MIM capacitor 202 discussed above. The example MIM capacitor 702 is similar to MIM capacitor 202 discussed above, but includes a bottom electrode via 362′ formed in via layer Vₓ that provides a direct conductive path between the bottom electrode cup 328 and the bottom electrode connection pad 360, which may provide a reduced resistance as compared with MIM capacitor 202 discussed above. The bottom electrode via 362′ may define a lateral extension from the bottom electrode cup 328, and may be formed concurrently with the bottom electrode cup 328, e.g., by depositing the via fill metal 410 (e.g., tungsten or other conformal metal) into a laterally elongated opening extending from the tub opening used to form the bottom electrode cup 328.

As noted above, in some examples the MIM capacitor 202 or 702 can be constructed between any two metal layers Mₓ and Mₓ₊₁ at any depth in the relevant integrated circuit structure. In some examples each metal layer Mₓ and Mₓ₊₁ may comprise a metal interconnect layer, e.g., an aluminum or copper interconnect layer, wherein the lower metal structures 380 in the lower metal layer Mₓ and upper metal structures 384 in the upper metal layer Mₓ₊₁ are formed by subtractive patterning (e.g., deposition, patterning, and etching), or using a damascene process, or in any other suitable manner.

1. A method of forming a metal-insulator-metal (MIM) capacitor in an integrated circuit structure, the method comprising:
forming a bottom electrode plate in a lower metal layer;
depositing an inter-metal dielectric layer over the bottom electrode plate;
patterning and etching the inter-metal dielectric layer to form a tub opening;
depositing a conformal fill metal in the tub opening;
depositing an insulator layer over the conformal fill metal in the tub opening;
depositing a top electrode layer over the insulator layer and extending into the tub opening;
performing a chemical mechanical planarization (CMP) process to remove upper portions of the top electrode layer, upper portions of the insulator layer, and upper portions of the conformal fill metal;
wherein (a) a portion of the conformal fill metal in the tub opening defines a bottom electrode cup, (c) a portion of the insulator layer in the tub opening defines an insulator cup, and (d) a portion of the top electrode layer in the tub opening defines a top electrode; and
forming a top electrode connection pad in an upper metal layer above the lower metal layer, wherein the top electrode connection pad is conductively connected to the top electrode.

2. The method of claim 1, wherein forming the bottom electrode plate in the lower metal layer comprises forming a metal silicide on a polysilicon region.

3. The method of claim 1, wherein the top electrode connection pad is formed by a damascene process.

4. The method of claim 1, wherein the upper metal layer comprises a metal interconnect layer.

5. The method of claim 1, wherein after forming the tub opening, the bottom electrode cup, the insulator cup, and the top electrode are formed without using any photomasks.

6. The method of claim 1, further comprising, after the CMP process and before forming the top electrode connection pad in the upper metal layer, depositing an etch stop layer extending over the bottom electrode cup, the insulator cup, and the top electrode.

7. The method of claim 1, comprising:
patterning and etching the inter-metal dielectric layer to concurrently form the tub opening and a bottom electrode via opening;
depositing the conformal fill metal in the tub opening and the bottom electrode via opening concurrently, wherein a portion of the conformal fill metal remaining in the bottom electrode via opening after the CMP process defines a bottom electrode via; and
forming a bottom electrode connection pad in the upper metal layer, wherein the bottom electrode connection pad is conductively connected to the bottom electrode cup through the bottom electrode via.

8. The method of claim 7, wherein:
the bottom electrode via opening is laterally spaced apart from the tub opening; and
the bottom electrode connection pad is conductively connected to the bottom electrode cup through the bottom electrode via and the bottom electrode plate.

9. The method of claim 7, wherein the bottom electrode via opening extends laterally from the tub opening, such that the bottom electrode via formed in the bottom electrode via opening extends laterally from the bottom electrode cup formed in the tub opening.

10. A method of forming an integrated circuit structure including a metal-insulator-metal (MIM) capacitor and an interconnect structure, the method comprising:
forming a lower interconnect element and a bottom electrode plate in a lower metal layer;
depositing an inter-metal dielectric layer over the lower interconnect element and the bottom electrode plate;
patterning and etching the inter-metal dielectric layer to form (a) a plurality of interconnect via openings over the lower interconnect element, (b) a tub opening over the bottom electrode plate, and (c) a bottom electrode via opening;
depositing a conformal fill metal extending into the plurality of interconnect via openings, the tub opening, and the bottom electrode via opening;
depositing an insulator layer over the conformal fill metal in the tub opening;
depositing a top electrode layer over the insulator layer and extending into the tub opening;
performing a chemical mechanical planarization (CMP) process to remove upper portions of the top electrode layer, insulator layer, and conformal fill metal;
wherein (a) a portion of the conformal fill metal in each interconnect via opening defines an interconnect via, (b) a portion of the conformal fill metal in the tub opening defines a bottom electrode cup, (c) a portion of the via fill metal in the bottom electrode via opening defines a bottom electrode via, (d) a portion of the insulator layer in the tub opening defines an insulator cup, and (e) a portion of the top electrode layer in the tub opening defines a top electrode; and
forming an upper interconnect element, a top electrode connection pad and a bottom electrode connection pad in an upper metal layer,
wherein the bottom electrode connection pad is conductively connected to the bottom electrode cup through the bottom electrode via.

11. The method of claim 10, wherein the lower metal layer comprises a silicided polysilicon layer, wherein the lower interconnect element comprises a first metal silicide region on a first polysilicon region and the bottom electrode plate comprises a second metal silicide region on a second polysilicon region.

12. The method of claim 10, wherein the upper interconnect element, the top electrode connection pad and bottom electrode connection pad are formed by a damascene process.

13. The method of claim 10, wherein the upper metal layer comprises a metal interconnect layer.

14. The method of claim 10, wherein after forming the tub opening, the bottom electrode cup, the insulator cup, and the top electrode are formed without using any photomasks.

15. The method of claim 10, further comprising, after the CMP process and before forming the top electrode connection pad and bottom electrode connection pad in the upper metal layer, depositing an etch stop layer over the bottom electrode cup, the bottom electrode via, the insulator cup, and the top electrode.

16. An integrated circuit structure, comprising:
a metal-insulator-metal (MIM) capacitor comprising:
a bottom electrode comprising:
a bottom electrode plate;
a bottom electrode cup formed from a conformal fill metal;
an insulator cup formed on the bottom electrode cup;
a top electrode formed in an opening defined by the insulator cup; and
a top electrode connection pad connected to the top electrode.

17. The integrated circuit structure of claim 16, further comprising:
an interconnect structure comprising:
a lower interconnect element;
an upper interconnect element; and
an interconnect via between the lower interconnect element and the upper interconnect element;
wherein the bottom electrode cup and the interconnect via are formed in a common via layer from the conformal fill metal.

18. The integrated circuit structure of claim 17, wherein:
the lower interconnect element and the bottom electrode plate are formed in a lower metal layer; and
the upper interconnect element and the top electrode connection pad are formed in an upper metal layer.

19. The integrated circuit structure of claim 18, wherein:
the lower metal layer comprises a silicide polysilicon layer; and
the upper metal layer comprises a damascene metal layer.

20. The integrated circuit structure of claim 17, wherein:
the lower interconnect element and the bottom electrode plate are formed in a lower metal layer; and
the upper interconnect element and the top electrode connection pad are formed in an upper metal layer above the lower metal layer.

21. The integrated circuit structure of claim 20, wherein the bottom electrode cup, the insulator cup, and the top electrode are formed between the lower metal layer and upper metal layer.

22. The integrated circuit structure of claim 16, further comprising:
a bottom electrode via; and
a bottom electrode connection pad connected to the bottom electrode via;
wherein the bottom electrode connection pad is conductively connected to the bottom electrode cup through the bottom electrode via; and
wherein the bottom electrode cup and the bottom electrode via are formed from the conformal fill metal.

23. The integrated circuit structure of claim 22, wherein the bottom electrode via is laterally spaced apart from the bottom electrode cup.

24. The integrated circuit structure of claim 22, wherein the bottom electrode via comprises a laterally elongated via extending laterally from the bottom electrode cup.
